(19) United States
(12) Patent Application Publication
(10) Pub. No.: US 2017/0047376 A1
(43) Pub. Date: Feb. 16, 2017

(54) SEMICONDUCTOR STORAGE DEVICE

(71) Applicant: HITACHI, LTD., Tokyo (JP)

(72) Inventors: Kenzo KUROTSUCHI, Tokyo (JP); Riichiro TAKEMURA, Tokyo (JP); Yoshitaka SASAGO, Tokyo (JP)

(21) Appl. No.: 15/307,126

(22) PCT Filed: Jun. 2, 2014
(86) PCT No.: PCT/JP2014/064571

§ 371 Date: Oct. 27, 2016

(51) Int. Cl. H01L 27/24; H01L 45/00

(52) U.S. Cl. CPC H01L 27/249; H01L 45/1253; H01L 45/122

(57) ABSTRACT

A semiconductor storage device includes: a semiconductor substrate; a first storage unit; a second storage unit including a plurality of the first storage units formed in a first direction parallel to the semiconductor substrate; a third storage unit including a plurality of the second storage units formed in a second direction perpendicular to the first direction and parallel to the semiconductor substrate; and a fourth storage unit including a plurality of the third storage units in a third direction perpendicular to the semiconductor substrate. A plurality of contacts coupling signal lines each configured to select an address in the second direction and the semiconductor substrate, is arranged in a region in which no interference with bit lines extending in the first direction occurs. Therefore, the semiconductor storage can perform reading and writing for large capacity at a high speed, and can be manufactured at a low cost, can be achieved.

### TECHNICAL FIELD

The present invention relates to a technique effective for applying to a semiconductor storage device including a rewritable nonvolatile memory, such as a phase-change memory, a ReRAM, an STT-MRAM, a memory having a charge storage layer, or a memory having an anti-fuse layer, or for applying to a storage system including the semiconductor storage device.

### BACKGROUND ART

Examples of the related art of the present technical field include PTL 1. This publication describes a technique of manufacturing a large-capacity semiconductor storage device by using a phase-change memory as a nonvolatile memory and coupling a plurality of bits in series to be chain-shaped. It is also described that “there is a problem that carriers enter a transistor from a diode so that characteristics of the transistor degrades in a semiconductor memory including the diode and the transistor coupled in series” (refer to an abstract). Furthermore, it is described that, “for example, the following operation is performed in a cell including memory cells each including this type of transistor and a phase-change element coupled in parallel, coupled in series, namely, in a chain cell” in paragraph [0044].

PTL 2 is disclosed as another example. This publication describes that “control electrodes 15, 25, 35, and 45 are formed stepwise at memory array end portions of different layers, and first to fourth word line contact plugs 55, 56, 57, and 58 to be coupled to the control electrodes each having a different depth are arranged so as to be coupled to each word line 59” (refer to paragraph [0016]).

PTL 3 is disclosed as another example. This publication describes that “contacts 349 provide selection lines 241, 242, 243, and 244 with electrical connection” (refer to paragraph) [0022]).

PTL 4 is disclosed as another example. This publication describes that “M2 wiring in multilayer wiring is used as word line shunt wiring WLSi” (refer to paragraph [0026].

### CITATION LIST

### Patent Literature

PTL 1: JP 2012-69830 A

PTL 2: JP 2008-140912 A

PTL 3: JP 2013-533628 W

PTL 4: JP 2011-060397 A

### SUMMARY OF INVENTION

### Technical Problem

In a technique of achieving large capacity of a semiconductor storage device with a three-dimensional structure and reducing bit costs, a reading bit line extends in a direction parallel to a silicon substrate and a first selection line (hereinafter, referred to as a Y selection line) extends in a direction the same as that of the reading bit line. Furthermore, a second selection line (referred to as an X selection line) extends in a direction parallel to the silicon substrate and also perpendicular to the reading bit line. The X selection line and the Y selection line that are used for a selection operation of a memory, are each coupled to the silicon substrate through a contact. It is necessary to drive the Y selection line at a high speed in order to cause a reading speed and a writing speed to be high-speed. Thus, the number of pieces of base wiring extending in a direction the same as that of the Y selection line, increases.

In this case, two problems occur. One of the two problems is that the contact coupling the Y selection line of a memory array in an upper layer and the silicon substrate, passes in proximity to a reading bit line of a memory array in a lower layer so that there is a possibility of an electrical short circuit (a short). The other is that the contact passes in proximity to the base wiring so that there is a possibility of an electrical short circuit (a short) there. Since the number of the pieces of base wiring extending in the direction the same as that of the Y selection line is large, it is difficult to pass a contact electrode with the base wiring avoided.

### Solution to Problem

In order to achieve the above object, the present invention is to adopt configurations described in the claims.

The present application includes a plurality of means for solving the above problems. As one example of the means, “a semiconductor storage device includes: a semiconductor substrate; a second storage unit including a plurality of first storage units in a first direction parallel to the semiconductor substrate; a third storage unit including a plurality of the second storage units in a second direction perpendicular to the first direction and parallel to the semiconductor substrate; and a fourth storage unit including a plurality of the third storage units in a third direction perpendicular to the semiconductor substrate. A plurality of contacts coupling signal lines each configured to select an address in the second direction and the semiconductor substrate, is arranged in a region in which no interference with bit lines extending in the first direction occurs”.

### Advantageous Effects of Invention

The semiconductor storage device that has high reliability, can perform reading and writing for large capacity at a high speed, and can be manufactured at a low cost, can be achieved.

### BRIEF DESCRIPTION OF DRAWINGS

FIG. 1 is an exemplary partial sectional configuration of memory arrays of a semiconductor storage device according to a first embodiment of the present invention.

FIG. 2 is another exemplary partial sectional configuration of the memory arrays of the semiconductor storage device according to the first embodiment of the present invention.

FIG. 3 is another exemplary partial sectional configuration of the memory arrays of the semiconductor storage device according to the first embodiment of the present invention.

FIG. 4 is an exemplary partial plan configuration of the memory arrays of the semiconductor storage device according to the first embodiment of the present invention.

FIG. 5 is another exemplary partial plan configuration of the memory arrays of the semiconductor storage device according to the first embodiment of the present invention.

FIG. 6 is an exemplary partial sectional configuration of memory arrays to be compared to the semiconductor storage device according to the first embodiment of the present invention.

FIG. 7 is another exemplary partial sectional configuration of the memory arrays to be compared to the semiconductor storage device according to the first embodiment of the present invention.

FIG. 8 is another exemplary partial sectional configuration of the memory arrays to be compared to the semiconductor storage device according to the first embodiment of the present invention.

FIG. 9 is an exemplary partial plan configuration of the memory arrays to be compared to the semiconductor storage device according to the first embodiment of the present invention.

FIG. 10 is an exemplary partial circuit configuration of the memory arrays of the semiconductor storage device according to the first embodiment of the present invention.

FIG. 11 is an exemplary circuit configuration of reading bit line selectors of the semiconductor storage device according to the first embodiment of the present invention.

FIG. 12 is an exemplary circuit configuration including global reading bit lines of the semiconductor storage device according to the first embodiment of the present invention.

FIG. 13 is an exemplary circuit configuration of a sense amplifier of the semiconductor storage device according to the first embodiment of the present invention.

FIG. 14 is an exemplary partial sectional configuration of a memory array of the semiconductor storage device according to the first embodiment of the present invention.

FIG. 15 is an exemplary partial plan configuration of the memory array of the semiconductor storage device according to the first embodiment of the present invention.

FIG. 16 is an exemplary partial plan configuration of memory arrays of a semiconductor storage device according to a second embodiment of the present invention.

FIG. 17 is an exemplary partial plan configuration of memory arrays of a semiconductor storage device according to a third embodiment of the present invention.

FIG. 18 is an exemplary partial plan configuration of memory arrays of a semiconductor storage device according to a fourth embodiment of the present invention.

FIG. 19 is another exemplary partial plan configuration of the memory arrays of the semiconductor storage device according to the fourth embodiment of the present invention.

FIG. 20 is an exemplary partial sectional configuration of memory arrays of a semiconductor storage device according to a fifth embodiment of the present invention.

### DESCRIPTION OF EMBODIMENTS

Embodiments will be described with the drawings below.

### First Embodiment

According to the present embodiment, an exemplary semiconductor storage device 1201 having memory arrays MA each having memory chains MC each having memory cells CELL, will be described.

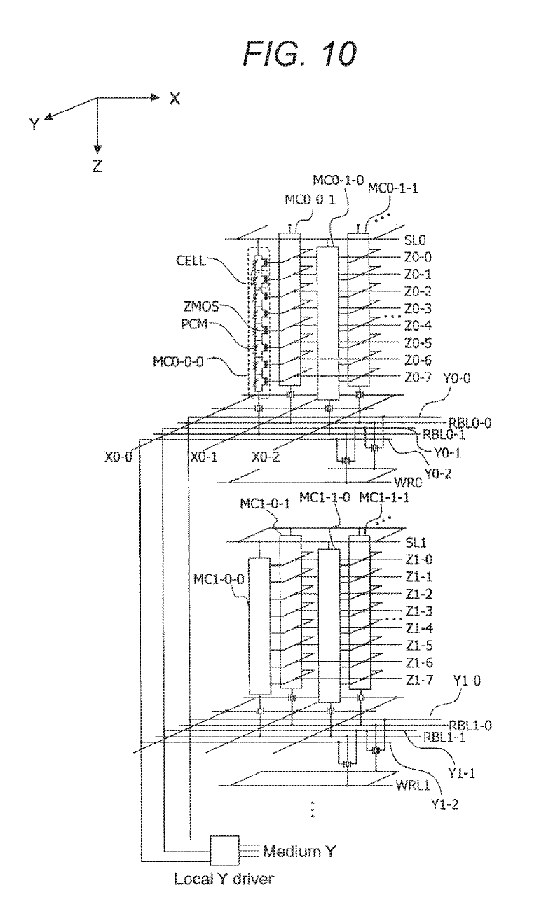

FIG. 10 is an exemplary partial circuit configuration of the memory arrays MA of the semiconductor storage device 1201 according to the present embodiment. The memory arrays MA each includes the plurality of memory chains MC. The memory chains MC each includes the plurality of memory cells CELL coupled in series. The memory cells CELL each includes one phase-change element PCM and one Z selection element ZMOS coupled in parallel. An example of coupling the one phase-change element PCM and the one Z selection element ZMOS in parallel, will be described here. Needless to say, coupling one phase-change element PCM and a plurality of Z selection elements ZMOS in parallel, coupling a plurality of phase-change elements PCM and one Z selection element ZMOS in parallel, or coupling a plurality of phase-change elements PCM and a plurality of Z selection elements ZMOS in parallel, can be made.

A Z direction is a direction perpendicular to a silicon substrate. An X direction and a Y direction are preferably perpendicular to the Z axis, and are also perpendicular to each other. In this manner, the plurality of memory cells present in the Z direction can be collectively formed by single piercing processing. Thus, manufacturing costs can be reduced. Reading bit lines preferably extend in the X direction or the Y direction. According to the present embodiment, the descriptions will be given with the reading bit lines that extend in the X direction and are parallel to Y selection lines.

A case where memory chains are layered so as to include four layers, is exemplified. Needless to say, at least five layers can be layered or the number of layers can be made so as to be less than four. There is a merit that memory capacity can increase by increasing the number of layers. There is another merit that manufacturing can be easily made by decreasing the number of layers.

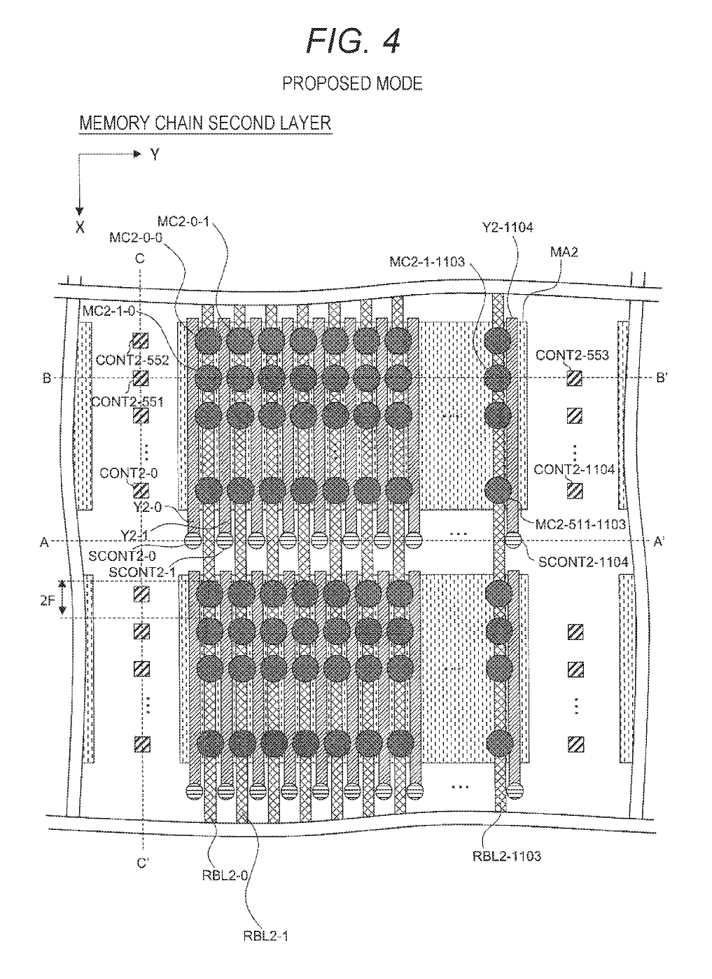

A schematic plan view of a memory chain second layer will be described with FIG. 4.

Memory arrays 2 in a second layer each include a plurality of memory chains MC present. A memory chain at an X address I and a Y address J in an H-th layer, is denoted with MC(H)-(I)-(J). A plurality of reading bit lines RBL extends in the X direction. A reading bit line at a Y address C in an A-th layer, is denoted with RBL(H)-(J). The reading bit lines RBL are shared with the plurality of memory arrays MA. The share can reduce contact areas of the reading bit lines, and the manufacturing can be made at a low cost with a chip area reduced. In addition, a plurality of Y selection lines Y extends in the X direction.

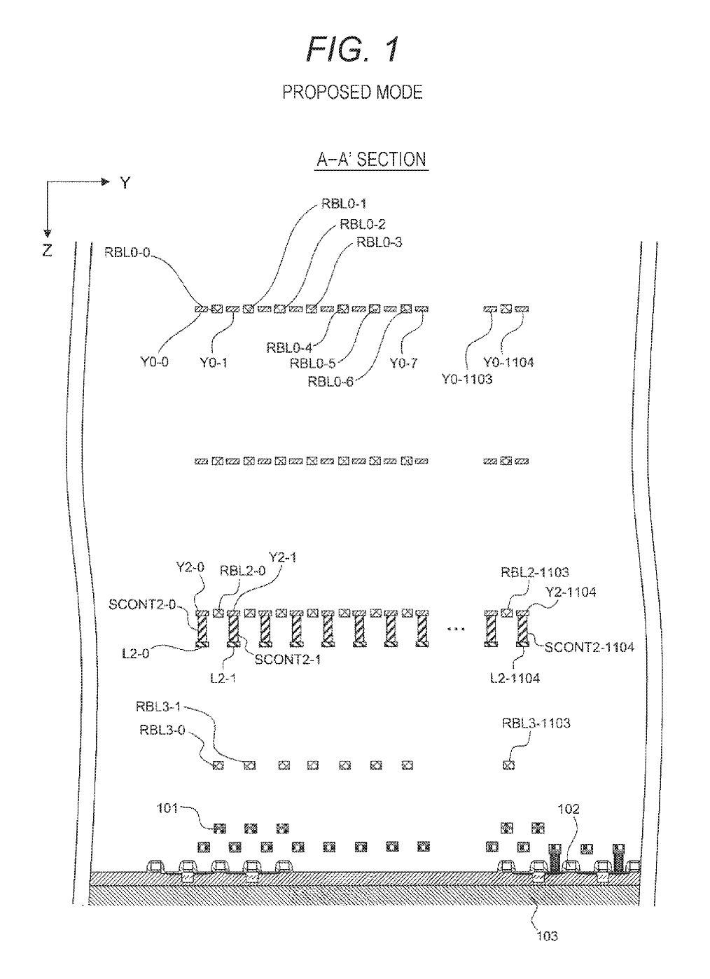

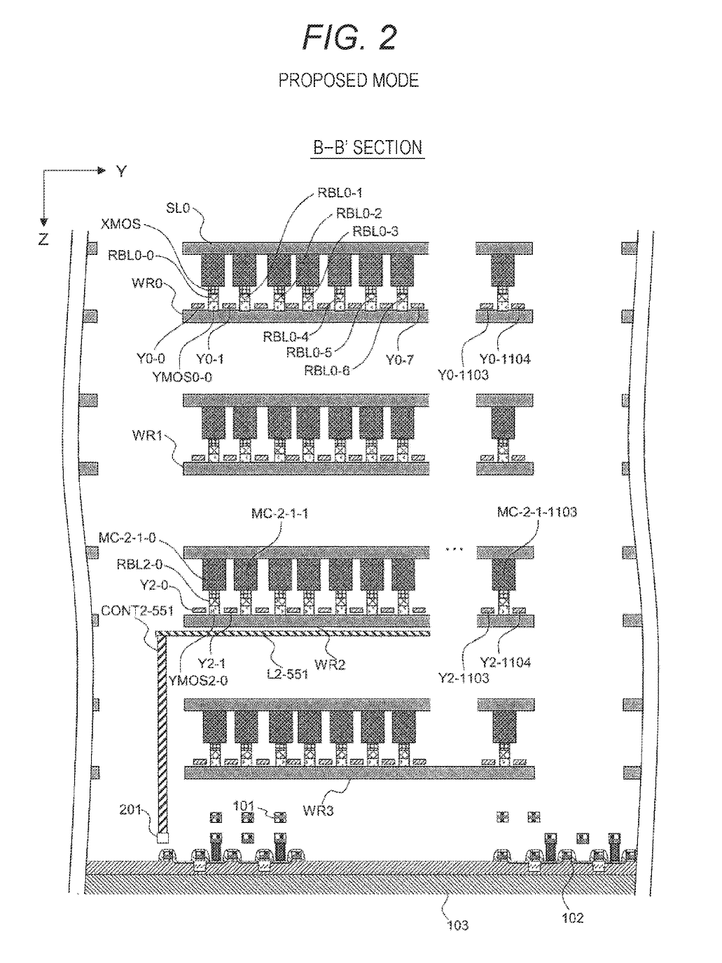

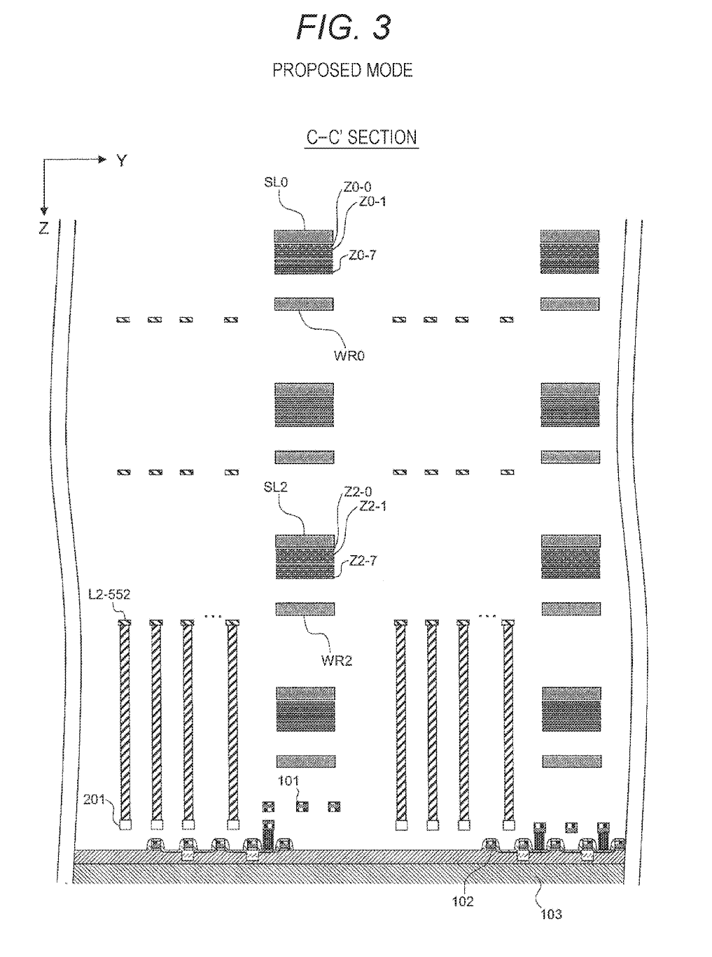

FIG. 1 illustrates a schematic sectional view taken along line A-A′ illustrated in FIG. 4. The Y selection lines Y are coupled to pieces of L-shaped wiring L through sub-contacts SCONT. Furthermore, the pieces of L-shaped wiring L are coupled to pieces of base contact wiring 201 through contacts CONT as illustrated in schematic sectional views taken along line B-B′ line and line C-C′ illustrated in FIGS. 2 and 3, respectively. Furthermore, the pieces of base contact wiring 201 are coupled to base MOSs 102 through connects (not illustrated). A distance between each of the Y selection lines and each of the base MOSs is shorten so that wiring resistance is reduced. As a result, a selection operation can be performed upon high-speed writing. It is required to perform the selection operation, for example, for 2 ns (nsec) upon the writing. The selection operation makes, for example, a transition from a state where a memory chain MC-2-0-0 has been selected and a memory chain MC-2-0-1 has not been selected to a state where the memory chain MC-2-0-0 has not been selected and the memory chain MC-2-0-1 has been selected, namely, a variation of a selection state of the memory cells CELL. Here, reading bit lines RBL3 in a third layer, such as an RBL3-0 and an RBL3-1, are not present in proximity to the contacts, for example, at a distance of 2F or less (F represents minimum processing dimensions). Furthermore, the pieces of base wiring 101 are not present in proximity to the contacts. The read bit lines are pieces of wiring used for the memory arrays MA, and the reading bit lines extend in the X direction. Since the contacts CONT are arranged at Y coordinates different from those of the memory arrays MA, it is achieved that interference between the contacts CONT and the reading bit lines RBL is avoided. Furthermore, the pieces of base wiring 101 include a large number of pieces of wiring extending in the X direction as described later. Thus, in a case where the contacts CONT are successively arranged in the Y direction, it is necessary to lay out the pieces of base wiring 101 to be present in proximity to the contacts CONT. However, in the present embodiment in which the contacts CONT are successively arranged in the X direction, for example, in a case where a CONT2-551 is arranged at a distance 2F from a CONT2-552 in the X direction in FIG. 4, a layout including the pieces of base wiring 101 not wired in proximity to the contacts CONT, can be made.

Here, the base MOSs 102 mean MOSs manufactured on the silicon substrate 103. The pieces of base wiring 101 mean pieces of wiring for signal lines, power source lines, and the like for driving the base MOSs 102. Signals driven by the base MOSs are used for, for example, the selection operation of the memory arrays. For example, the signals are used for driving Y selection lines Y. The base MOSs 102 arranged near the Y selection lines drive the Y selection lines Y so that the transition speed of the Y selection lines can improve and a selection operation relating to Y addresses can be performed at a high speed. Thus, a high-speed writing operation can be achieved. A reason why the number of pieces of wiring extending in the X direction is larger than the number of pieces of wiring extending in the Y direction regarding the pieces of base wiring, will be described. The number of selection operations when one page is written, is expressed by the following expression (Mathematical Formula 1).

The number of selection operations=page size/the number of simultaneous writing bits (Mathematical Formula 1)

A phase-change memory requires, for example, a relatively large writing current of 40 μA. Thus, the number of simultaneous writing bits is, for example, 32 bits that is small, and the number of selection operations increases. For example, in a case where the page size has 8832 B including 8 KB+a spare region of 640 B, the number of selection operations results in 2208.

In order to perform reading at a high speed, the number of bits with which the reading can be simultaneously performed upon the reading, is preferably made to increase. Therefore, a length in the Y direction perpendicular to reading bit lines is preferably longer than a length in the X direction in a page region being units of the reading and the writing. A case where the page region ranges over four memory chains MC in the X direction, will be exemplified and described below.

The 2208 selection operations per page are preferably performed with Y selection lines. In a case where the Y selection lines are used, the number of selection operations of the Y selection lines results in 2208, and the number of selection operations of X selection lines results in four. Meanwhile, in a case where the X selection lines are used, the number of selection operations of the Y selection lines results in 552, and the number of selection operations of the X selection lines results in 2208. Thus, the total number of selection operations of the X selection lines and the Y selection lines increases.

Since the selection number of the Y selection lines is large, the number of signal lines for controlling the Y selection lines increases and the width of the signal lines widens. Therefore, the number of the pieces of wiring extending in the X direction is made so as to be larger than the number of the pieces of wiring extending in the Y direction regarding the pieces of base wiring.

The Y selection lines each have a role of designating an address to be written together with a role of designating whether the writing is performed. The X selection lines each and Z selection lines each have a role of designating an address to be written.

Since the Y selection lines are derived with the pieces of L-shaped wiring L, the lengths of the Y selection lines are preferably, approximately twice the lengths of the X selection lines. Regarding wiring of the pieces of L-shaped wiring L, the left halves of the memory arrays MA (the side on which the Y addresses are small) are wired from the sub-contacts SCONT in an upper direction (−X direction) and then are folded and bent in a left direction (−Y direction) so as to be coupled to contacts CONT on the left sides of the memory arrays MA. The right halves of the memory arrays MA (the side on which the Y addresses are large) are wired from the sub-contacts SCONT in the upper direction (−X direction), and then are folded and bent in a right direction (the Y direction) so as to be coupled to contacts CONT on the right sides of the memory arrays MA. The lengths of the memory arrays MA in the X direction are substantially the same as the lengths of the Y selection lines, and the lengths in the Y direction are substantially the same as the lengths of the X selection lines. The number of memory chains in the X direction is preferably a multiple of two. In this manner, a control circuit is simplified and the chip area is reduced so that an effect of reducing the manufacturing costs is acquired. Note that, needless to say, a redundant amount of rows can be added to the number of memory chains MC in the X direction. In this case, there is an effect of reducing a loss ratio of products due to manufacturing defects. According to the present embodiment, a case where the number of memory chains in the X direction is 512, will be exemplified and described. The number of memory chains in the Y direction preferably, slightly exceeds a multiple of two. In this manner, in a case where the page size is made to be a total data size of a data body including the number of bits of a multiple of two and additional data, such as an error correction code (ECC) of the data body, the control circuit is simplified and the chip area is reduced. Thus, there is an effect that the manufacturing costs can be reduced. Note that, needless to say, a redundant amount of columns can be added to the number of memory chains MC in the Y direction. In this case, there is an effect of reducing a loss ratio of products due to manufacturing defects. According to the present embodiment, a case where the number of memory chains in the Y direction is 1104, will be exemplified and described. The size of the additional data is preferably, approximately 8% of the size of the body data. Needless to say, 2 to 30% can be made. According to the present embodiment, one memory array in one layer stores data in an amount of 552 KB. X addresses include 0 to 511, Y addresses include 0 to 1103, and Z addresses include 0 to 7. In the data, body data includes 512 KB and additional data includes 40 KB. Note that, needless to say, the data size of the memory array is different from the page size, a block size being a unit of deletion, and a super block size being a unit of defect management.

Note that, interlayer insulating films are not illustrated.

FIG. 3 illustrates eight Z selection lines Z for each of the four layers. Selection of the memory cells CELL in the memory chains MC is performed with the Z selection lines Z.

Regarding the contacts CONT, FIG. 4 illustrates only the contacts CONT relating to the memory arrays 2. Contacts CONT of adjacent memory arrays in the same layer are omitted.

Characteristics of the present embodiment will be clearly described. The Y selection lines Y for designating the Y addresses, the pieces of base contact wiring 201, the contacts CONT coupled to the pieces of L-shaped wiring L, are arranged in the X direction in parallel to the reading bit lines extending in the X direction.

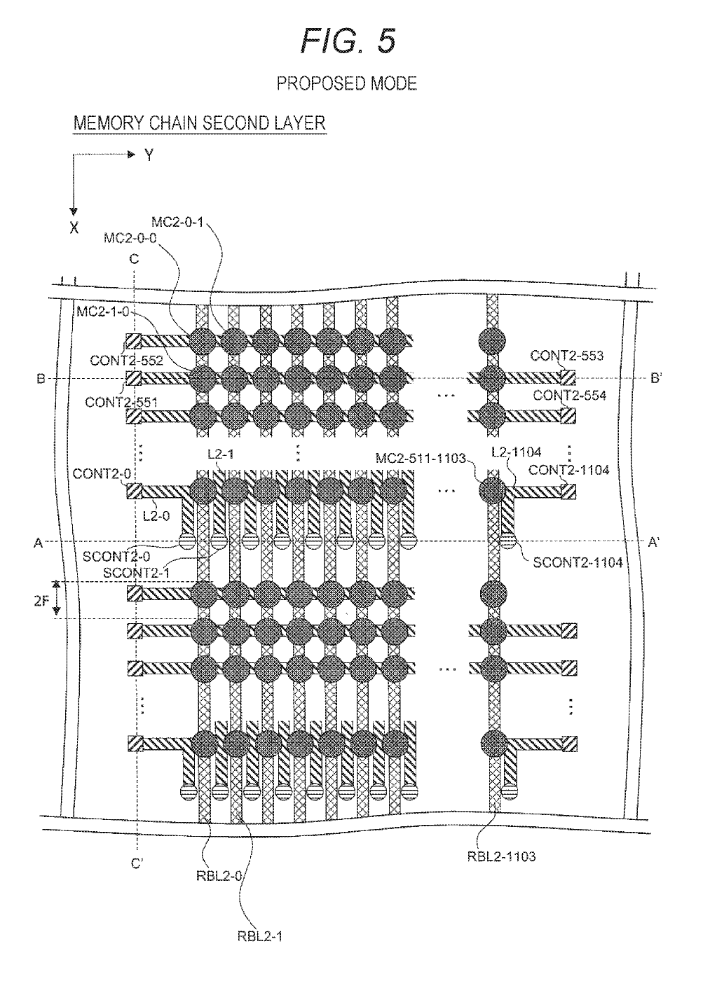

As illustrated in FIG. 5, the pieces of L-shaped wiring L are preferably L-shaped. In this case, a layout can be made with standard process rules. Thus, there is an effect that a development period can shorten. Note that, needless to say, the L-shape is not necessarily required. For example, needless to say, wiring including an arc corresponding to a quarter of a circle, can be made. In this case, since no folded and bent portions are present, there is an effect that reliability of the semiconductor storage device 1201 improves. Note that, in the arc corresponding to a quarter of a circle, a chord g of the arc satisfies the following expression (Mathematical Formula 2) with respect to a radius r of the arc.

g=r×\sqrt{2} [Mathematical Formula 2]

Needless to say, the arc is not necessarily, strictly a quarter of a circle. When a range in which the chord g of the arc satisfies the following expression (Mathematical Formula 3), is achieved, a chip area to be additionally required can be small and the semiconductor storage device 1201 can be manufactured at a low cost.

r×\sqrt{2}×0.6<g<r×\sqrt{2}×1.4 [Mathematical Formula 3]

Needless to say, wiring oblique at 45 degrees with respect to the Y direction can be made. In this case, since the lengths of the pieces of L-shaped wiring L shorten, high-speed drive of the Y selection lines can be made. Thus, there is an effect that the speed of the writing operation improves.

X selection elements XMOS and Y selection elements YMOS preferably use double-gate NMOSFETs. The use of the double-gate MOSFETs can widen the gate widths of the MOSFETs in comparison to use of planar MOSFETs. Thus, current necessary for writing of the phase-change elements PCM is easily secured. Therefore, there is an advantage that a yield of the semiconductor storage device 1201 can improve. In addition, driving force of the MOSFETs improves so that the number of memory cells CELL included in the memory chains MC can increase. Furthermore, a cell area of each of the memory chains MC is made to be 4F2 smaller than 6 to 8F2 (the square of F) in a case where the planar MOSFETs are used. Thus, the semiconductor storage device 1201 having large capacity can be achieved. The double-gate NMOSFETs each include two gate electrodes. When an on-voltage is applied to both of the gate electrodes, a MOS is turned on (in a low resistance state). In a case where the on-voltage is applied to only one of the gate electrodes or in a case where an off-voltage is applied to all the gate electrodes, the MOS is turned off (in a high resistance state).

Examples of a material for the pieces of wiring and the contacts that can be used include Ti, TiN, W, Al, and Cu. Needless to say, a layered structure is made with a plurality of materials as necessary.

Upon writing, current can flow from source electrodes SL to writing electrodes WR. Upon deletion, current can flow from the writing electrodes WR to the source electrodes SL. The Z selection lines Z are used for selecting the Z addresses of the memory cells in the memory chains. A case where one memory chain includes eight memory cells, will be exemplified and described.

Next, an exemplary mode to be compared to the present embodiment, will be described. A semiconductor storage device based on the mode different from that according to the present embodiment, is provided.

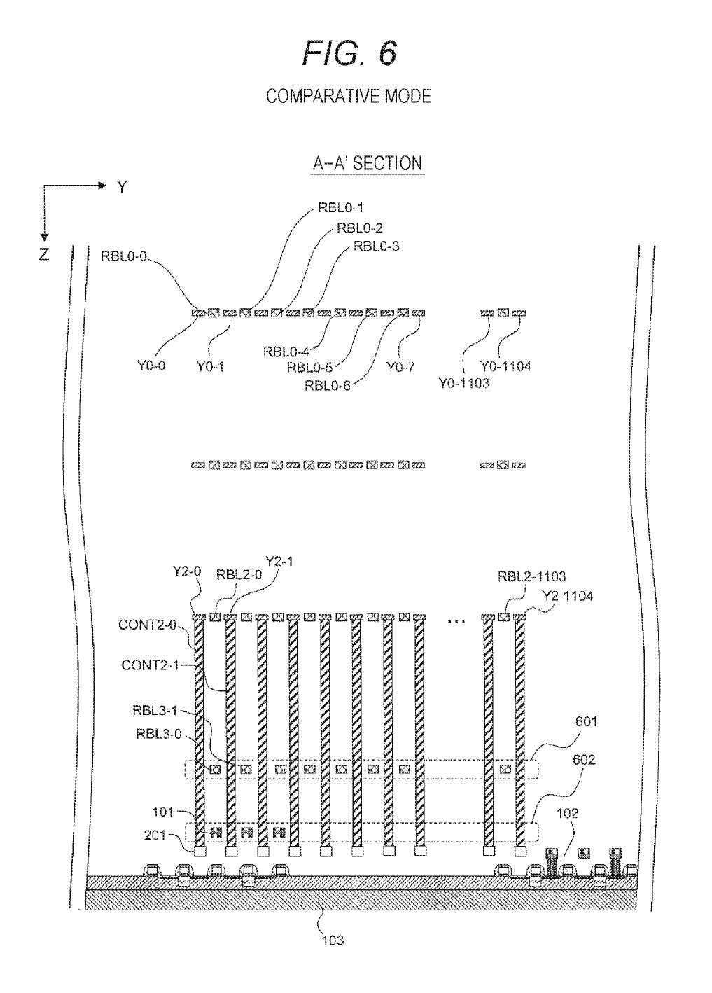

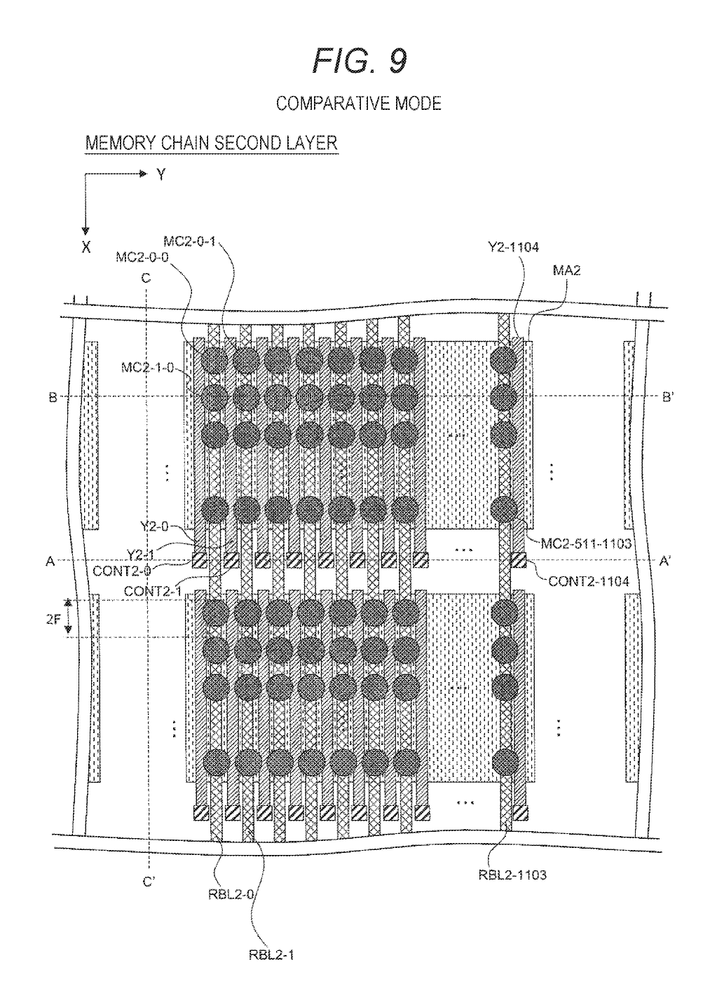

FIG. 9 illustrates a schematic plan view of the comparative mode. Contacts CONT coupling Y selection lines and pieces of base contact wiring 201 are positioned at Y addresses the same as those of the Y selection lines Y. In this case, as illustrated in a schematic view of an A-A′ section of FIG. 6, since contacts CONT in a second layer pass through a lower layer, in this case, in proximity to reading bit lines in a third layer, there is a possibility that a short circuit electrically occurs in a short-circuit hazardous region 601 with the lower layer reading bit lines, resulting in a defective. Furthermore, since the contacts CONT pass in proximity to pieces of base wiring 101, there is a possibility that short circuit occurs in a short-circuit hazardous region 602 with pieces of lower layer wiring, resulting in a defective.

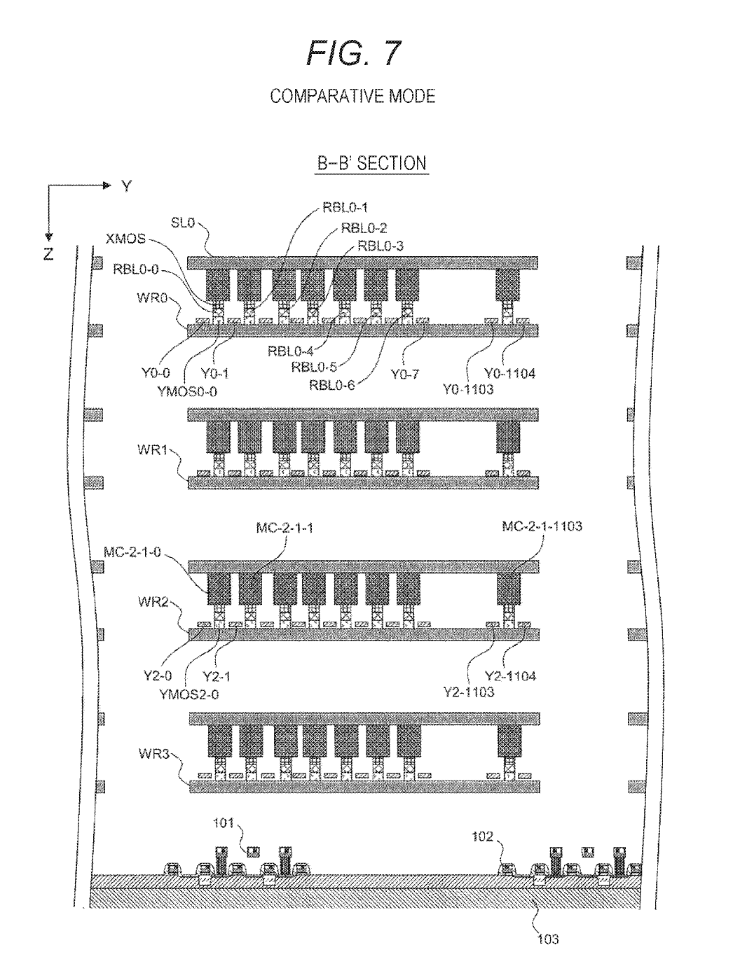

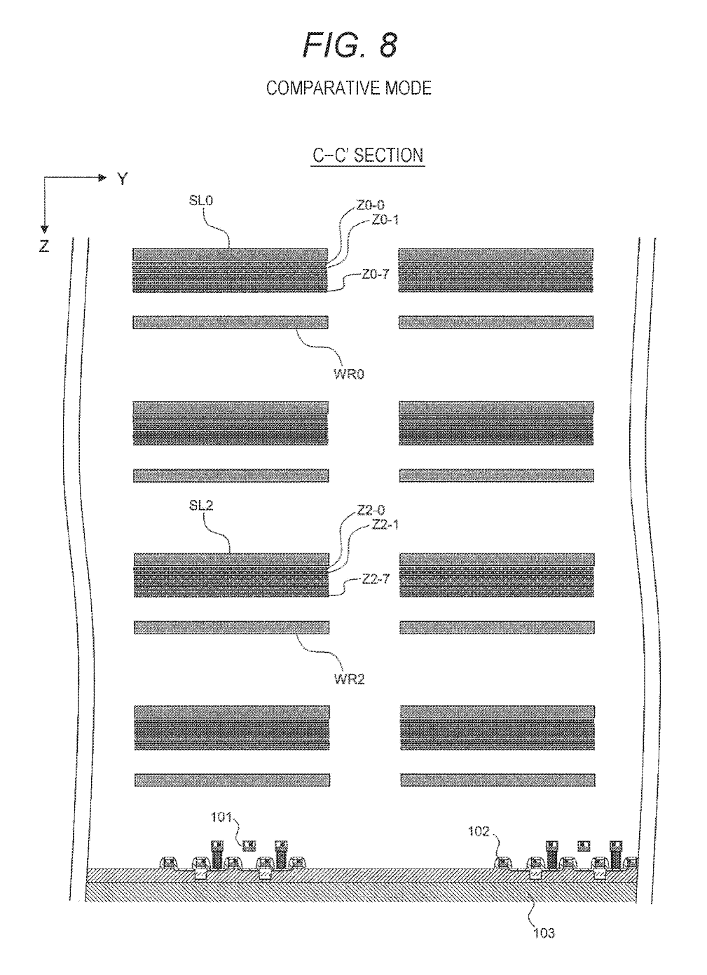

FIGS. 7 and 8 illustrate schematic views of B-B′ and C-C′ sections, respectively. The comparative mode includes no pieces of L-shaped wiring L coupling sub-contacts SCONT and the contacts CONT and no sub-contacts SCONT coupling the Y selection lines Y and the pieces of L-shaped wiring L, differently from the present embodiment. The contacts CONT couple the Y selection lines Y and the pieces of base contact wiring 201.

Referring back to the descriptions of the present embodiment, the more detailed descriptions will be given.

The schematic circuit diagram of the partial memory arrays and a Y selection line drive circuit Local Y driver, is illustrated in FIG. 10.

In a Y selection layer including a plurality of layers, for example, a Y selection line Y0-0 in a zeroth layer and a Y selection line Y1-0 in a first layer are coupled to each other and are also coupled to the Local Y driver. The Local Y driver is driven with a power source voltage line and a GND line that are not illustrated, and a medium Y selection line signal Medium Y. Here, the Y selection lines in the plurality of layers are simultaneously driven so that a circuit area of the Y selection line drive circuit Local Y driver can be reduced, not exceeding circuit areas of memory arrays in which the corresponding Y selection lines are used. In a case where the simultaneous drive is not performed, the area of the Y selection line drive circuit Local Y driver is made to be larger than those of the memory arrays, and the ratio of the areas occupied by the memory arrays to the chip area decreases. Thus, the manufacturing costs increase.

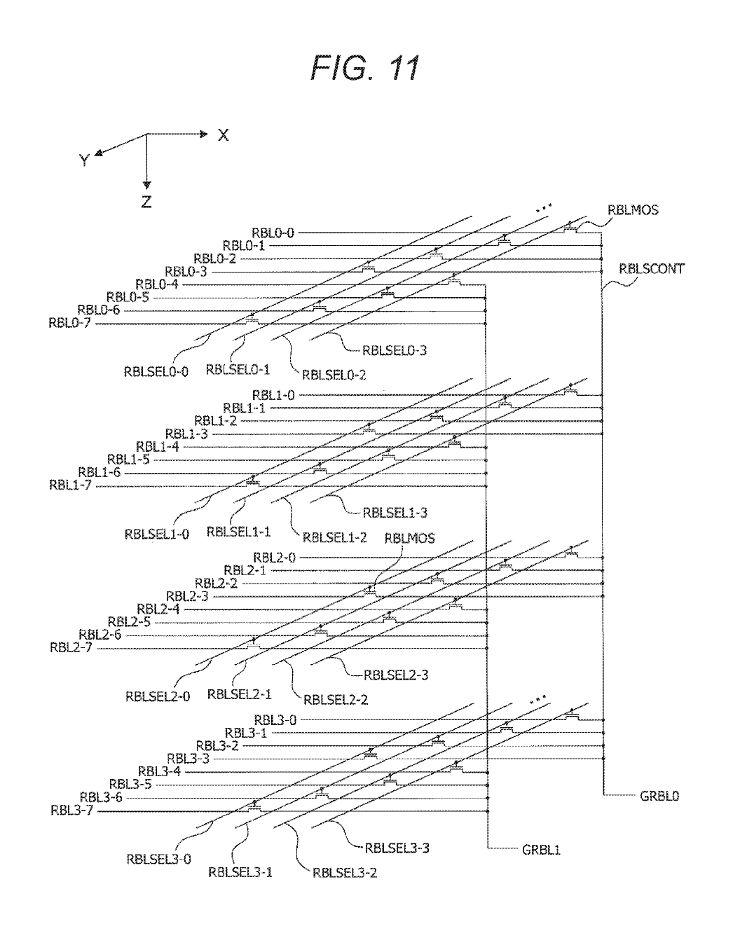

FIG. 11 illustrates a schematic circuit diagram of reading bit line selectors RBLS. The use of the reading bit line selectors RBLS can reduce the number of reading bit line contacts coupling the reading bit lines and the pieces of base wiring, can prevent wiring flexibility from degrading due to the contacts, and can achieve the semiconductor storage device 1201 having a high writing-data transfer rate. A plurality of reading bit lines RBL is coupled to global reading bit lines through reading bit line selection elements RBLMOS. Here, an example in which the number of layers is four and totally sixteen reading bit lines RBL including four from each of the layers are coupled to one global reading bit lines GRBL, will be described.

Reading bit line selection lines RBLSEL are individually coupled to the plurality of reading bit line selection elements RBLMOS. In the figure, the number of reading bit line selection lines RBLSEL is 16, and each is coupled to two reading bit line selection elements RBLMOS. Thirty two reading bit line selection elements RBLMOS are illustrated.

Selecting one of the reading bit line selection lines RBLSEL can couple one reading bit line RBL out of sixteen reading bit lines RBL to a global reading bit line GRBL. The reading bit line selection lines RBLSEL can be simultaneously formed with, for example, the Y selection elements YMOS. The simultaneous formation can reduce the manufacturing costs and the semiconductor storage device 1201 can be achieved at a low cost.

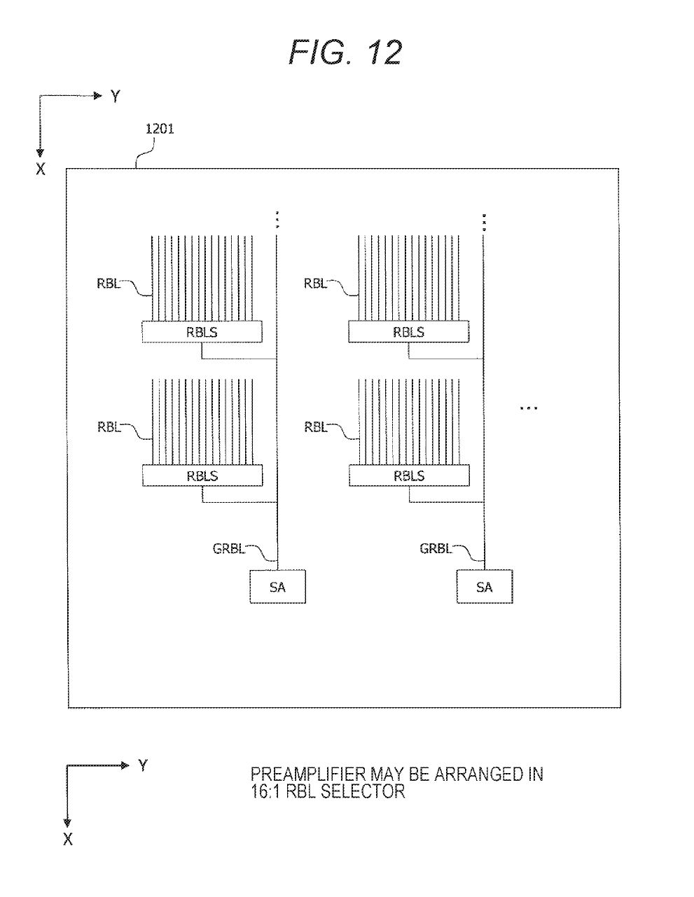

FIG. 12 illustrates a schematic circuit diagram illustrating relationship between reading bit line selectors RBLS and a sense amplifier SA. The plurality of reading bit line selectors RBLS is coupled to one global reading bit line GRBL.

A preamplifier that amplifies signals of the reading bit lines RBL can be arranged in the reading bit line selection lines RBLSEL. In this manner, there is an effect that a sensing speed increases and a reading data transfer speed improves. However, there is a demerit that a circuit area increases and the manufacturing costs increases. As an amplifier circuit, a method of amplifying a differential signal with respect to a dummy bit line by a current mirror circuit, can be used.

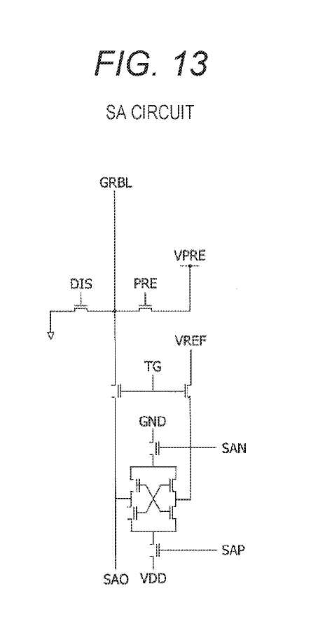

FIG. 13 illustrates a schematic circuit diagram of the sense amplifier.

A reading method will be described. First, a precharge signal PRE is input so that a precharge voltage VPRE is applied to a bit line. For example, a voltage of 0.5 V is applied. After that, a memory cell CELL to be read is selected. When a value of the memory cell CELL is “1”, resistance of a phase-change element PCM included in the memory cell CELL is low and electric charges move through the phase-change element PCM. For example, the voltage of the bit line decreases to 0.1V. Meanwhile, the value of the memory cell CELL is “0”, the resistance of the phase-change element PCM included in the memory cell CELL is high and the electric charges barely move through the phase-change element PCM. The voltage of the bit line remains at approximately 0.5 V. A differential amplifier circuit amplifies a voltage level difference between the voltage of the bit line and a reference voltage VREF, and then outputs a result to a sense amplifier output SAO. A control circuit not illustrated is used so as to output the result from the sense amplifier output SAO to the exterior of the semiconductor storage device 1201 through a data input/output pad not illustrated.

A discharge circuit operates with a discharge signal DIS input therein, and can cause reading bit lines RBL to be 0 V. 0 V is provided after the reading has been completed. Noise generation caused by the reading bit lines can be reduced and the semiconductor storage device 1201 having high reliability can be achieved. SAN and SAP represent sense amplifier operating signals. The sense amplifier operating signals SAP and SAN supply a power source voltage VDD and a ground voltage GND to the sense amplifier, respectively. A differential amplifier circuit enabler TG is a signal line for making input of the differential amplifier circuit to be effective.

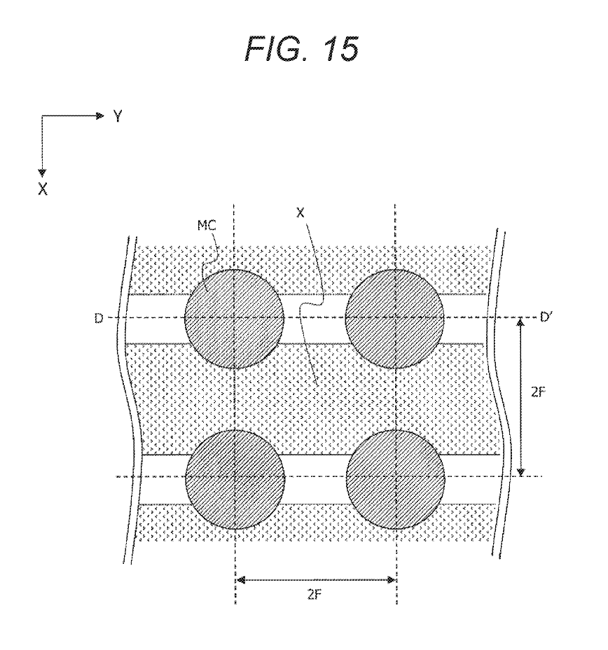

FIG. 15 illustrates a partial memory array MA.

Memory chains MC are arranged at intervals of 2F. X selection destinations extend in the Y direction.

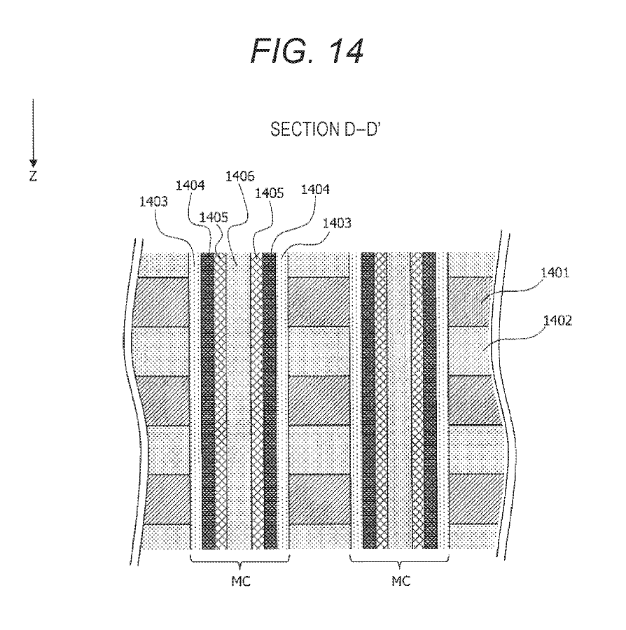

FIG. 14 illustrates a schematic sectional view taken along line D-D′ of FIG. 15. Partial memory chains MC are illustrated.

A plurality of Z selection elements ZMOS and a plurality of phase-change elements PCM are illustrated. The Z selection elements ZMOS and the phase-change elements PCM include a silicon oxide film 1406, a gate oxide film 1403, a silicon channel 1404, a phase-change material 1405, a Z selection transistor gate electrode 1401, and an interlayer insulating film 1402.

Vertical gate all around n-channel MOSFETs (GAA-NMOSFET) are preferably used for the Z selection elements ZMOS. The NMOSFETs having current driving force higher than that of a PMOSFET are used so that the number of phase-change elements PCM included in the memory chains MC increases. Thus, the semiconductor storage device 1201 having large capacity can be achieved. Needless to say, PMOSs can be used. The use of the vertical MOSFETs can make the size of a transistor to be 4F2 smaller than that in a case where planar MOSs are used. Thus, large capacity can be made. With a GAA structure, a gate width can widen in comparison to a case where the planar MOSs are used. Thus, large capacity can be achieved by improving the driving force of the MOSs and increasing the number of memory cells CELL included in the phase-change chains MC. In a case where the PMOSs are used, a voltage to be applied to a gate electrode of a non-selected Z selection transistor can be low in comparison to a case where the NMOSs are used so that gate resisting pressure of the Z selection MOSs is small. Thus, there is an effect that the reliability of the semiconductor storage device 1201 improves.

As a part of a material of the phase-change elements PCM, a chalcogenide material, in particular, germanium-antimony-tellurium alloy (GeSbTe alloy) can be used. The chalcogenide material can take two metastable states including an amorphous state (a noncrystalline state) and a crystalline state. Values of electric resistance in the respective states are different from each other. That is, high resistance is acquired in the amorphous state and low resistance is acquired in the crystalline state. A difference of the electric resistance between the states is used so that values of “0” and “1” can be stored. “0” is defined as the amorphous state and “1” is defined as the crystalline state. Rewriting “0” to “1” is defined as deletion, and rewriting “1” to “0” is defined as writing. Current flows into the phase-change elements PCM and Joule heat is generated so that writing is performed. In order to perform the deletion, the phase-change elements PCM are retained at, at least, a crystallization temperature during a certain period so as to be crystallized. In order to perform the writing, heating is performed at a melting point or more and then rapid cooling is performed so that amorphization (vitrification) is made. Needless to say, the phase-change elements PCM can take at least ternary values.

Using phase-change elements that have already been applied to products as storage elements, can shorten a development period. There is an effect that the semiconductor storage device 1201 can be shipped for a short period. Note that, according to the present embodiment, as phase-change elements, substances that undergo a change in phase between a crystal and an amorphous solid, will be exemplified and described. Needless to say, substances that undergo a change in phase between a crystal A and a crystal B can be used. Here, the crystal A and the crystal B are crystals each having a different crystal structure. Note that, according to the present embodiment, a case where the phase-change elements are used as storage elements, will be exemplified and described. Needless to say, examples of the storage elements that can be used include ReRAMs, STT-MRAMs (spin injection MRAMs), charge-storage memories, such as floating gate memories and charge trap memories. Using the ReRAMs requiring a small rewriting current can increase the number of storage elements included in one memory chain MU. Thus, there is an effect that the semiconductor storage device 1201 having large capacity can be achieved. Using the STT-MRAMs having a high rewriting speed acquires an effect that the semiconductor storage device 1201 having a large writing data rate can be achieved. Furthermore, using the charge-storage memories requiring a small writing current acquires an effect that the semiconductor storage device 1201 having low power consumption can be achieved. According to the present embodiment, a case where the phase-change elements are used as the storage elements, has been described.

Flowing a writing current into the phase-change elements PCM generates Joule heat so that the writing and the deletion are performed. The writing current is, for example, 40 μA, and a deleting current is, for example, 20 μA. Note that, flowing current into adjacent Z selection MOSs generates Joule heat so that the writing and the deletion can be logically performed.

Upon the writing, a writing current of, for example, 40 μA flows in a selected memory chain MC. Meanwhile, current hardly flows into unselected memory chains MC.

Bundling deletion is preferably performed upon the deletion. For a plurality of memory chains MC, the bundling deletion simultaneously deletes all bits included in the memory chains MC and flows current into mainly Z selection MOSs. This is because wrong deletion of a memory cell adjacent to a deleting region easily occurs when a part of memory chains is about to be deleted. Furthermore, when the plurality of memory chains is collectively deleted, heat from one memory chain is used so that an adjacent memory chain can be heated or an escape of heat can be reduced. Thus, electric energy necessary for the deletion can be reduced and the semiconductor storage device 1201 capable of performing deletion at a high speed can be achieved. Note that, a reason why the escape of heat can be reduced is as follows: A memory chain adjacent to a certain memory chain is heated so that a difference in temperature between the memory chains decreases. According to Fourier's law in which heat flux density and the difference in temperature are in proportion to each other, a heat flux between the memory chains decreases. Furthermore, even in a case where the phase-change elements have high resistance and a high voltage is required in order to cause each of the phase-change elements itself to generate heat, flowing current into mainly the Z selection elements ZMOS causes the Z selection elements ZMOS to generate heat so that a voltage necessary for the deletion is reduced. An amount of further stable heat release upon the deletion can be achieved.

In order to select a phase-change element PCM, a Z selection element ZMOS in the same memory cell CELL is turned off so that current flows into the phase-change element instead of the Z selection element.

### Second Embodiment

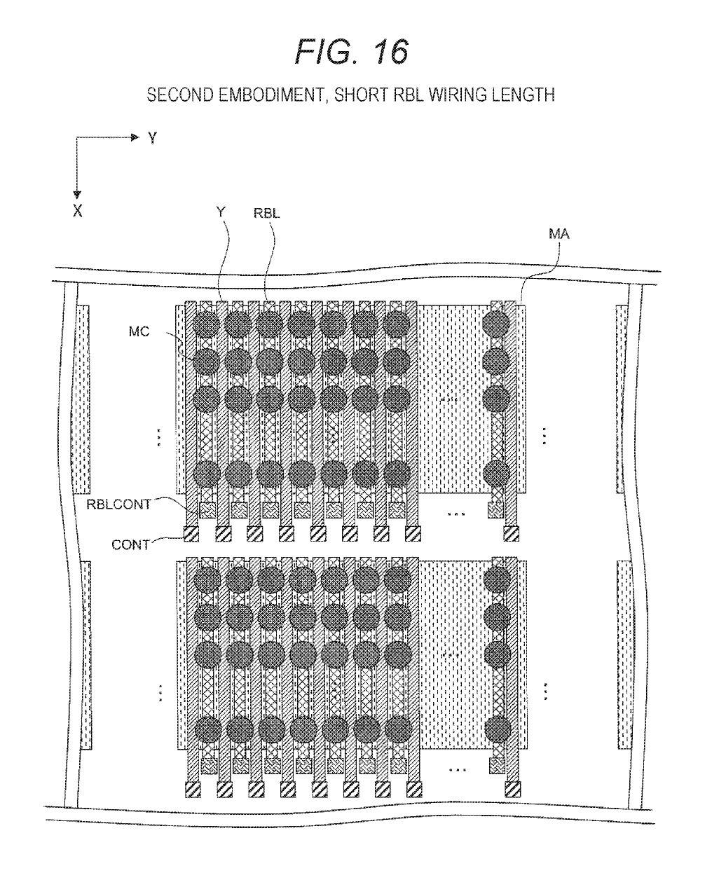

In the present embodiment, an exemplary semiconductor storage device with low manufacturing costs will be described with FIG. 16

FIG. 16 is an exemplary view of a configuration of the semiconductor storage device 1201 according to the second embodiment.

Descriptions of portions having functions the same as those of the already described configurations denoted with the same reference signs illustrated in FIGS. 1 to 5, will be omitted.

The present embodiment is characterized in that the length of reading bit lines RBL is substantially the same as or is shorter than the length of Y selection lines Y. Specifically, when the length of the Y selection lines Y is defined as LY, and the length of the reading bit lines RBL is defined as LRBL, the following expression (Mathematical Formula 4) is satisfied.

LRBL<1.5×LY (Mathematical Formula 4)

The length of each memory array in a X direction is shorter than the length of the RBLs, and is shorter than the length of the Y selection lines Y. Therefore, in a case where the length of the RBLs is shorter than 0.75×LY, the RBLs shorten and the memory arrays also shorten so that the rate of the memory arrays to an entire chip decreases. As a result, a problem that memory capacity decreases, occurs.

Descriptions will be given in a case where the global reading bit lines illustrated in FIG. 11 have been formed in a layer of pieces of base wiring.

The reading bit lines RBL are coupled to the pieces of base wiring through reading bit line contacts RBLCONT. Note that, needless to say, the reading bit lines RBL can be coupled to the pieces of base wiring through reading bit line selectors RBLS simultaneously formed with Y selection lines, similarly to the first embodiment. In this case, the reading bit line contacts couple the reading bit lines RBL and reading bit line selection elements RBLSEL. The reading bit line selection elements RBLSEL are coupled to the global reading bit line GRBL formed in the layer of the base wiring through reading bit line selector contacts RBLSCONT illustrated in FIG. 11.

According to the present embodiment, a layer of pieces of L-shaped wiring L and sub-contacts SCONT are not required. Therefore, there is no need of process costs for forming these. There is an effect that the semiconductor storage device 1201 can be manufactured at a low cost. Meanwhile, the number of the reading bit line contacts RBLCONT or, in some cases, the number of the reading bit line selectors RBLS, in the chip, increases. Thus, there is a problem that the capacity of the semiconductor storage device 1201 decreases. The present embodiment is preferably applied to a use in which the semiconductor storage device 1201 having a low price and low capacity is required for a storage device of a toy camera having low pixels or a netbook being a personal computer for connecting with a net, characterized by a low price.

### Third Embodiment

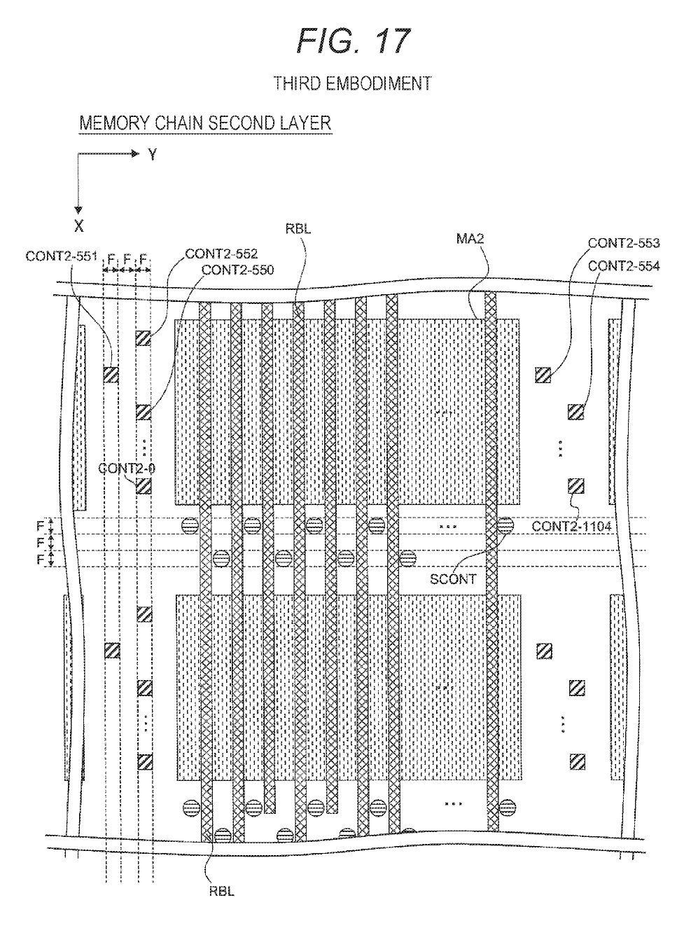

In the present embodiment, an exemplary semiconductor storage device having high reliability and a high yield will be described with FIG. 17.

FIG. 17 is an exemplary schematic circuit diagram of a part of the semiconductor storage device 1201 according to the third embodiment.

Descriptions of portions having functions the same as those of the already described configuration denoted with the same reference signs illustrated in FIG. 1 will be omitted.

According to the present embodiment, contacts are arranged so as not to be on a straight line, and are characterized by zigzag arrangement.

As illustrated in FIG. 17, the contacts CONT are arranged so that Y addresses are alternately slightly shifted. A case where a shift amount is 2F is illustrated. For example, a CONT2-552 and a CONT2-550 are at the same Y coordinate. However, a Y coordinate of a CONT2-551 is offset by −2F in comparison to the Y coordinate of the CONT2-552. In this manner, the contacts can be prevented from being short-circuited with each other. During operation of the semiconductor storage device 1201, occurrence of failures decreases. The semiconductor storage device 1201 having high reliability can be achieved. A probability that the contacts are short-circuited due to a manufacturing defect decreases so that the semiconductor storage device 1201 having a high yield can be achieved.

Note that, as illustrated in FIG. 17, similar zigzag arrangement can be used for sub-contacts SCONT.

Needless to say, applying the zigzag arrangement only to the sub-contacts SCONT, applying the zigzag arrangement only to the contacts CONT, and furthermore, applying the zigzag arrangement to both of the sub-contacts SCONT and the contacts CONT can be made.

Note that, the present embodiment is used so that a chip area required for the contacts increases. Thus, there is a problem that manufacturing costs increases.

In consideration of current manufacturing techniques, 2F is appropriate for the shift amount of the contacts (an offset amount) OF. However, a range of the following expression (Mathematical Formula 5) can be used.

0.5F≦OF≦5F (Mathematical Formula 5)

The contacts CONT are denoted with squares in FIG. 17. In fact, the shape of the contacts CONT is approximate to a circle. Even when the shift amount is 1F, an effect that the reliability improves is acquired. For example, in a case where the shape of the contacts is assumed to be a perfect circle, when the contacts having a diameter of 1F are arranged at 2F intervals in an X direction, a distance between the contacts is 1F in a case where the shift amount OF is 0F. In a case where the shift amount OF is, for example, 0.5F, according to the Pythagorean theorem, the distance d of the contacts satisfies the following expression: d>1F as shown in the following expression (Mathematical Formula 6). That is, the distance d between the contacts can be made so as to be larger than F.

d=(\sqrt{(2²+0.5²)}−1)F=1.06F [Mathematical Formula 6]

Meanwhile, when the shift amount OF is made so as to be larger than 5F, influence of an increase of an area of the contacts, to be given to an increase of the chip area increases. Thus, chip manufacturing costs rises.

### Fourth Embodiment

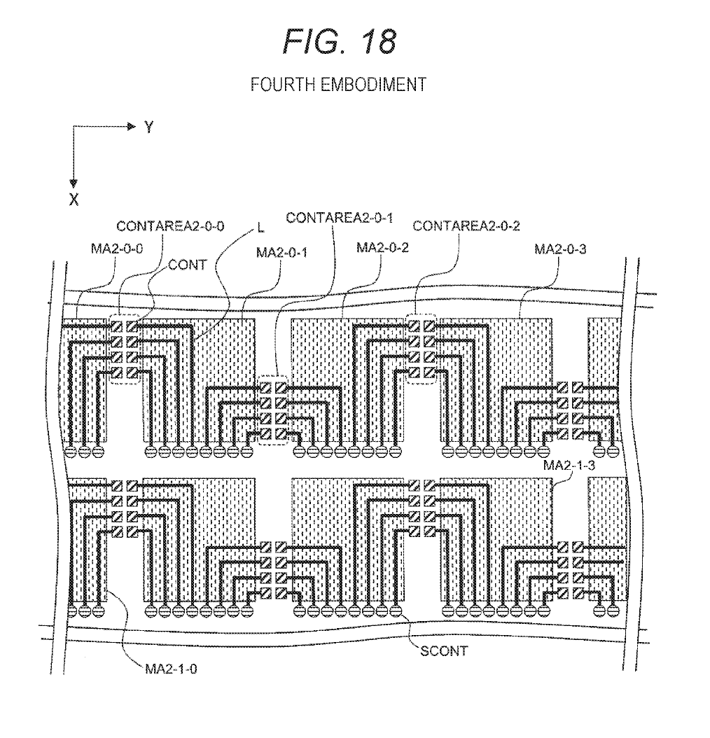

In the present embodiment, an exemplary semiconductor storage device having a further high-speed writing data transfer speed will be described with FIG. 18.

The present embodiment is characterized in that contact formed regions CONTAREA are at an X coordinate the same as that of upper halves of memory arrays and the other contact formed regions CONTAREA are at an X coordinate the same as that of lower halves of the memory arrays. For example, a contact formed region CONTAREA2-0-0 and a contact formed region CONTAREA2-0-2 are formed at an X coordinate the same as that of upper halves of memory arrays MA. A contact formed region CONTAREA2-0-1 is formed at an X coordinate different from that of the contact formed region CONTAREA2-0-0, and is formed at the X coordinate the same as that of lower halves of the memory arrays MA. That is, the contact formed regions CONTAREA are arranged so as to be staggered.

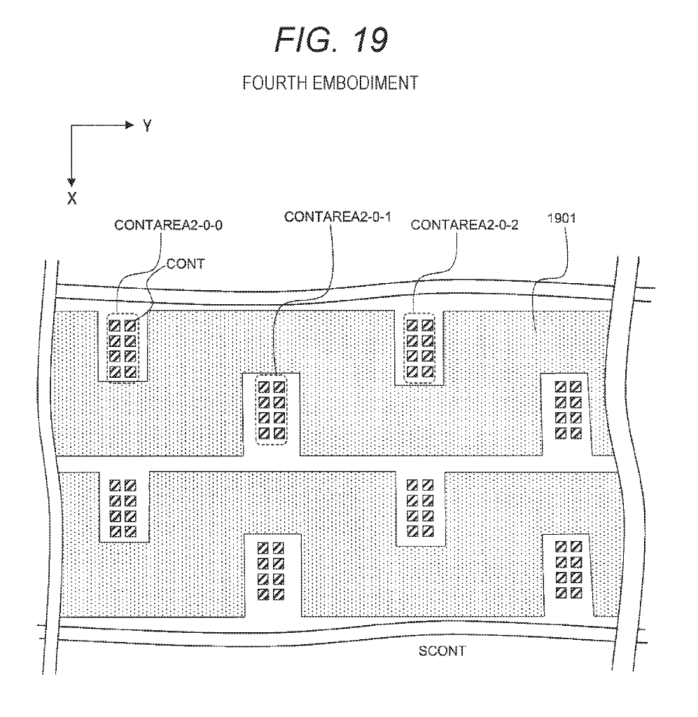

In this manner, as illustrated in FIG. 19, the widths of Y direction signal wiring possible regions 1901 in an X direction can widen. That is, the number of signal lines extending in a Y direction can increase and the width can widen. Thus, the writing data transfer speed can be made so as to be further high-speed in comparison to that according to the first embodiment. Meanwhile, the rate of an area of memory arrays to a chip area decreases. Thus, there is a problem that capacity of the semiconductor 1201 decreases. The present embodiment is preferably applied to, for example, the semiconductor storage device 1201 to be used for a cache memory of an SSD, including a battery-backed-up DRAM, in a field in which a requirement for speed is more severe than a requirement for capacity.

Note that, the wiring shapes of pieces of L-shaped wiring L are also varied with variations of coordinates of the contacts CONT with respect to the first embodiment. Furthermore, the wiring shapes of the pieces of L-shaped wiring L are made so as to have different shapes in accordance with the memory arrays. For example, the shape of L-shaped wiring of a memory array MA2-0-1 is different from the shape of a memory array MA-2-0-2. Desirably, pieces of L-shaped wiring having the same shape are preferably arranged in alternate memory arrays. The shape of the L-shaped wiring of the memory array MA2-0-1 and the shape of a memory array MA-2-0-3 are the same in the example of FIG. 18. The number of types of shapes of the pieces of L-shaped wiring is reduced so as to be two. Thus, inspection working hours of a manufacturing process can shorten. There is an effect that timing of product shipments can move forward.

Note that, the illustration is made so that the number of sub-contacts SCONT corresponding to each of the memory arrays MA is eight. Needless to say, the number of sub-contacts SCONT and the number of contacts CONT actually exceed eight.

### Fifth Embodiment

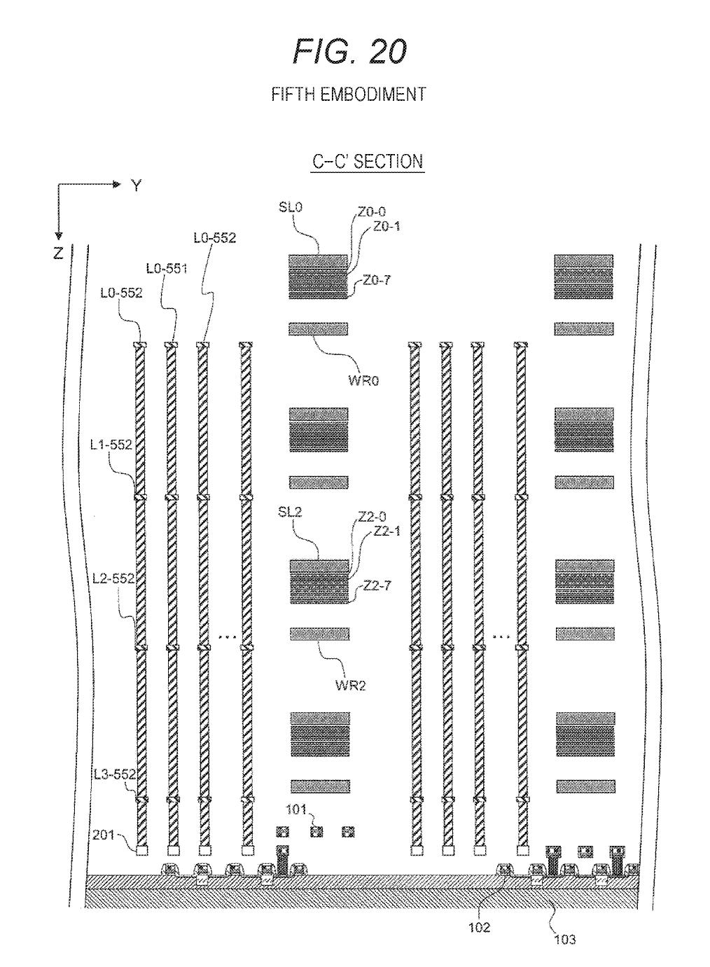

In the present embodiment, an exemplary semiconductor storage device having further large capacity, will be described with FIG. 20.

The present embodiment is characterized in that Y selection lines Y in a plurality of layers are electrically coupled, and contacts CONT coupling a memory chain zeroth layer and a memory chain first layer and contacts CONT coupling the memory chain first layer and a memory chain second layer are at the same X coordinate.

In this manner, an area to be consumed by the contacts CONT is reduced so that manufacturing costs of the semiconductor storage devices 1201 can be reduced.

Selection of a layer upon writing and upon deletion is performed with a writing electrode WR. Selection of a layer upon reading is performed with reading bit lines RBL.

Furthermore, the contacts CONT coupling the memory chain zeroth layer and the memory chain first layer and the contacts CONT coupling the memory chain first layer and the memory chain second layer can be arranged so as to be at the same Y coordinate. In this manner, the area consumed by the contacts CONT can be further reduced. Note that, unevenness in a Z direction at a region at which contacts overlap each other increases in size. Thus, there is a problem that lithography (exposure processing) is made to be difficult in a manufacturing process.

Preferably, the Y selection lines Y are coupled through pieces of L-shaped wiring L and the contacts CONT. In this manner, short circuits due to interference of the reading bit lines RBL and the contacts CONT as described in the first embodiment can be reduced.

Furthermore, after pieces of L-shaped wiring L for three layers are formed, the contacts CONT for four layers are collectively formed, and then pieces of L-shaped wiring L in the zeroth layer can be formed, instead of forming the contacts CONT every layer. In this case, there is an effect that the manufacturing costs can be reduced. Note that, there is a problem that difficulty of the manufacturing process increases.

Piercing processing for coupling the four layers can be performed by single dry etching, with the pieces of L-shaped wiring L as stoppers. In this case, X coordinates of the pieces of L-shaped wiring are made to be the same. Y coordinates are individually shifted, for example, by 1F and the pieces of L-shaped wiring are formed so that pieces of L-shaped wiring L in a lower layer slightly protrude from pieces of L-shaped wiring L in an upper layer, for example, by 1F2 (the square of F). After that, the dry etching is performed so as to expose parts of the Ls in each of the four layers. In this manner, the pieces of L-shaped wiring L in all the four layers can be coupled to pieces of base contact wiring 201 during the single piercing processing and the single contact forming process.

### REFERENCE SIGNS LIST

101 base wiring
102 base MOS
103 silicon substrate
201 base contact wiring
601 short-circuit hazardous region with lower layer reading bit lines
602 short-circuit hazardous region with pieces of lower wiring
1401 Z selection transistor gate electrode
1402 interlayer insulating film
1403 gate oxide film
1404 silicon channel
1405 phase-change material
1406 silicon oxide film
1901 Y direction signal wiring possible region
CELL memory cell
CONTAREA contact formed region
DIS discharge signal
F minimum processing dimensions
GND ground voltage
GRBL global reading bit line
L L-shaped wiring
Local Y driver Y selection line drive circuit
MA memory array
MC memory chain
Medium Y medium Y selection line signal
PCM phase-change element
PRE precharge signal
RBL reading bit line
RBLS reading bit line selector
RBLSEL reading bit line selection signal
SAN, SAP sense amplifier enablers
SAO sense amplifier output
SCONT sub-contact
SL source electrode
TG differential amplifier circuit enabler
VDD power source voltage
VPRE precharge voltage
VREF reference voltage
WR writing electrode
X X selection line
XMOS X selection element
Y Y selection line
YMOS Y selection element
Z Z selection line
ZMOS Z selection element

1. A semiconductor storage device comprising:
a semiconductor substrate;
a first storage unit;
a second storage unit including a plurality of the first storage units formed in a first direction parallel to the semiconductor substrate;
a third storage unit including a plurality of the second storage units formed in a second direction perpendicular to the first direction and parallel to the semiconductor substrate; and
a fourth storage unit including a plurality of the third storage units in a third direction perpendicular to the semiconductor substrate,
wherein a plurality of contacts coupling signal lines each configured to select an address in the second direction and the semiconductor substrate, is arranged in a region in which no interference with bit lines extending in the first direction occurs.

2. The semiconductor storage device according to claim 1,
wherein a direction in which no interference with the bit lines occurs is the first direction.

3. The semiconductor storage device according to claim 1,
wherein the bit lines are reading bit lines.

4. The semiconductor storage device according to claim 1,
wherein the first storage unit is a phase-change memory.

5. The semiconductor storage device according to claim 1,
wherein the contacts and the signal lines each configured to select an address in the second direction are coupled through wiring.

6. The semiconductor storage device according to claim 5,
wherein the wiring is folded and bent at an angle of 90 degrees.

7. The semiconductor storage device according to claim 5,
wherein the wiring is L-shaped.

8. The semiconductor storage device according to claim 5,
wherein the wiring has an arc in shape and a chord g of the arc satisfies the following expression (Mathematical Formula 3) with respect to a radius r of the arc.
r×\sqrt{2}×0.6<g<r×\sqrt{2}×1.4 [Mathematical Formula 3]

9. The semiconductor storage device according to claim 5,
wherein the wiring is at an angle of 45 degrees to the first direction, and is parallel to the semiconductor substrate.

10. The semiconductor storage device according to claim 1, further comprising:
a selection circuit configured to couple one of the plurality of bit lines to a sense amplifier.

11. A semiconductor storage device comprising:
a semiconductor substrate;
a first storage unit;
a second storage unit including a plurality of the first storage units formed in a first direction parallel to the semiconductor substrate;
a third storage unit including a plurality of the second storage units formed in a second direction perpendicular to the first direction and parallel to the semiconductor substrate; and
a fourth storage unit including a plurality of the third storage units formed in a third direction perpendicular to the semiconductor substrate,
wherein an array circuit configured to control the plurality of storage units in the third direction, is shared with signal lines each configured to select an address in the second direction, and simultaneously drives the signal lines.

12. The semiconductor storage device according to claim 11,
wherein selection of an address in the third direction is performed with a writing plate electrode.

13. The semiconductor storage device according to claim 11, further comprising:
a plurality of contacts coupling the signal lines each configured to select an address in the second direction and the semiconductor substrate,
wherein the plurality of contacts is layered at the same coordinates in the first direction and in the second direction through wiring.

14. A semiconductor storage device comprising:
a semiconductor substrate;
a first storage unit;
a second storage unit including a plurality of the first storage units formed in a first direction parallel to the semiconductor substrate;
a third storage unit including a plurality of the second storage units formed in a second direction perpendicular to the first direction and parallel to the semiconductor substrate; and
a fourth storage unit including a plurality of the third storage units formed in a third direction perpendicular to the semiconductor substrate,
wherein a plurality of contacts coupling signal lines each configured to select an address in the second direction and the semiconductor storage device, forms a column, and
the column is arranged not to be on a straight line, a shift OF is formed, and an amount of the shift OF satisfies the following expression:
0.5F≦OF≦5F
where F represents minimum processing dimensions.

15. A semiconductor storage device comprising:
a semiconductor substrate;
a first storage unit;
a second storage unit including a plurality of the first storage units formed in a first direction parallel to the semiconductor substrate;
a third storage unit including a plurality of the second storage units formed in a second direction perpendicular to the first direction and parallel to the semiconductor substrate;
a fourth storage unit including a plurality of the third storage units formed in a third direction perpendicular to the semiconductor substrate; and
contact formed regions each in which a plurality of contacts coupling signal lines each configured to select an address in the second direction and the semiconductor substrate, densely aggregates,
wherein the contact formed regions are arranged so as to be staggered in the second direction.
